(19) United States
(12) Patent Application Publication
(10) Pub. No.: US 2013/0050967 A1
(43) Pub. Date: Feb. 28, 2013

(54) FUNCTIONAL DEVICE-EMBEDDED SUBSTRATE

(71) Applicants: Daisuke Ohshima, Tokyo (JP); Katsumi Kikuchi, Tokyo (JP); Yoshiki Nakashima, Tokyo (JP); Kentaro Mori, Tokyo (JP); Shintaro Yamamichi, Tokyo (JP)

(72) Inventors: Daisuke Ohshima, Tokyo (JP); Katsumi Kikuchi, Tokyo (JP); Yoshiki Nakashima, Tokyo (JP); Kentaro Mori, Tokyo (JP); Shintaro Yamamichi, Tokyo (JP)

(73) Assignee: NEC CORPORATION, Minato-ku, Tokyo (JP)

(21) Appl. No.: 13/634,088

(22) PCT Filed: Jan. 19, 2011
(86) PCT No.: PCT/JP11/50839

§ 371 Date: Oct. 16, 2012

(30) Foreign Application Priority Data
Mar. 16, 2010 (JP) 2010-059316

(51) Int. Cl. H05K 1/18

(52) U.S. Cl. 361/764

(57) ABSTRACT

An object of the present invention is to provide a functional device-embedded substrate that can be thinned and suppress occurrence of warpage. The present invention provides a functional device-embedded substrate including at least a functional device including an electrode terminal, and a covering insulating layer covering at least an electrode terminal surface and a side surface of the functional device, the functional device-embedded substrate including a first pillar structure around the functional device inside the covering insulating layer, the first pillar structure including a material having a thermal expansion coefficient between thermal expansion coefficients of the functional device and the covering insulating layer, wherein the first pillar structure is arranged at a position where a shortest distance from a side surface of the functional device to a side surface of the first pillar structure is smaller than a thickness of the functional device.

### TECHNICAL FIELD

The present invention relates to a functional device-embedded substrate with a functional device such as a semiconductor chip embedded therein.

### BACKGROUND ART

For downsizing of electronic apparatuses such as mobile phones, techniques for thinning semiconductor devices that occupy a majority of the volumes of such apparatuses are being developed. As an example thereof, as disclosed in patent literatures 1 to 3, there is a technique in which a semiconductor chip is embedded in a wiring substrate. Furthermore, as disclosed in patent literature 4, there is a technique in which a wiring layer on the front side and a wiring layer on the back side of a functional device-embedded substrate are electrically connected by vias penetrating through an area surrounding the embedded semiconductor chip. Accordingly, stacking of such functional device-embedded substrate on another substrate enables effective use of the mounting area.

In each of the functional device-embedded substrates described in patent literatures 1 to 3, a recess portion is formed in a core substrate comprised of a resin, a semiconductor chip is buried in the recess portion with a terminal surface of the semiconductor chip facing up, and a wiring layer is formed on the electrode terminals. Use of the core substrate suppress occurrence of warpage of the substrate.

Also, in the functional device-embedded substrate described in patent literature 4, in order to suppress warpage, reinforcements are provided in side areas of a semiconductor chip buried in a core layer.

### CITATION LIST

### Patent Literature

Patent Literature 1: JP2001-332863A
Patent Literature 2: JP2001-339165A
Patent Literature 3: JP2002-246504A
Patent Literature 4: JP2006-261246A

### SUMMARY OF INVENTION

### Technical Problem

However, in each of the functional device-embedded substrates described in patent literatures 1 to 3, in order to prevent warpage, a core substrate having a certain degree of thickness is required, and if the core substrate is thinned in order to make the functional device-embedded substrate thinner, warpage may occur.

In the functional device-embedded substrate described in patent literature 4, it is difficult to form interlayer vias electrically that connects upper and lower wiring layers in the reinforcements. Also, the area in which the reinforcements are arranged is an outer peripheral portion of the substrate, and areas in the vicinity of end faces of the semiconductor chip where stress concentrates most are not reinforced.

Therefore, the present invention has been made in view of the aforementioned problems, and an object of the present invention is to provide a functional device-embedded substrate that can be thinned and can suppress occurrence of warpage.

### Solution to Problem

As a result of the present inventors' diligent study to achieve the above object, it has been found that in a functional device-embedded substrate, plural types of materials having largely different thermal expansion coefficients are mixed in the embedded substrate, and thus, stress occurs on an interface between the materials, resulting in warpage of the embedded substrate and damage of the semiconductor chip.

Therefore, the present invention provides

a functional device-embedded substrate comprising at least a functional device including an electrode terminal, and a covering insulating layer covering at least an electrode terminal surface and a side surface of the functional device, wherein

the functional device-embedded substrate including a first pillar structure around the functional device inside the covering insulating layer, the first pillar structure being comprised of a material having a thermal expansion coefficient between thermal expansion coefficients of the functional device and the covering insulating layer,

wherein the first pillar structure is arranged at a position where a shortest distance from a side surface of the functional device to a side surface of the first pillar structure is smaller than a thickness of the functional device.

### Advantageous Effects of Invention

In the present invention, a pillar structure having a predetermined thermal expansion coefficient is arranged in the vicinity of a functional device, thereby resulting in relaxation of a stress generated on an interface between a covering insulating layer and a functional device. Accordingly, the functional device-embedded substrate according to the present invention can reduce an occurrence of warpage.

### BRIEF DESCRIPTION OF DRAWINGS

FIG. 1 is a schematic cross-sectional diagram illustrating an example configuration of a functional device-embedded substrate according to the present exemplary embodiment.

FIG. 2 is a schematic cross-sectional diagram illustrating an example configuration of a functional device-embedded substrate according to the present exemplary embodiment.

FIG. 3 is a schematic cross-sectional diagram illustrating an example configuration of a functional device-embedded substrate according to the present exemplary embodiment.

FIG. 4 is a schematic cross-sectional diagram illustrating an example configuration of a functional device-embedded substrate according to the present exemplary embodiment.

FIG. 5 is a schematic cross-sectional diagram illustrating an example configuration of a functional device-embedded substrate according to the present exemplary embodiment.

FIG. 6 is a schematic cross-sectional diagram illustrating an example configuration of a functional device-embedded substrate according to the present exemplary embodiment.

FIG. 7 is a schematic cross-sectional diagram illustrating an example configuration of a functional device-embedded substrate according to the present exemplary embodiment.

FIG. 8 is a cross-sectional process diagram for illustrating a process of manufacturing the functional device-embedded substrate illustrated in FIG. 1.

FIG. 9 is a cross-sectional process diagram for illustrating a process of manufacturing the functional device-embedded substrate illustrated in FIG. 2.

FIG. 10 is a cross-sectional process diagram for illustrating a process of manufacturing the functional device-embedded substrate illustrated in FIG. 3.

FIG. 11 illustrates a cross-section along arrow X in FIG. 1 and is a horizontal cross-sectional diagram illustrating an example arrangement of first pillar structures.

FIG. 12 illustrates a cross-section along arrow X in FIG. 1 and is a horizontal cross-sectional diagram illustrating an example arrangement of first pillar structures.

FIG. 13 illustrates a cross-section along arrow X in FIG. 1 and is a horizontal cross-sectional diagram illustrating an example arrangement of first pillar structures and second pillar structures.

FIG. 14 illustrates a cross-section along arrow X in FIG. 1 and is a horizontal cross-sectional diagram illustrating an example arrangement of first pillar structures and second pillar structures.

FIG. 15 illustrates a cross-section along arrow X in FIG. 1 and is a horizontal cross-sectional diagram illustrating an example arrangement of first pillar structures and second pillar structures.

### DESCRIPTION OF EMBODIMENTS

A functional device-embedded substrate according to the present invention is a functional device-embedded substrate including at least a functional device including an electrode terminal and a covering insulating layer covering at least an electrode terminal surface and a side surface of the functional device. Furthermore, the functional device-embedded substrate includes a first pillar structure around the functional device inside the covering insulating layer, and the first pillar structure being comprised of a material having a thermal expansion coefficient between thermal expansion coefficients of the functional device and the covering insulating layer. The first pillar structure is arranged at a position where a shortest distance d1 from the functional device to the first pillar structure is smaller than a thickness of the functional device.

In the present invention, a first pillar structure comprised of a material having a thermal expansion coefficient between thermal expansion coefficients of a functional device and a covering insulating layer is arranged in the vicinity of a functional device. With such configuration, a part of the covering insulating layer that is in an area including the first pillar structure can be regarded as having a reduced thermal expansion coefficient, thereby substantively reducing the difference in thermal expansion coefficient between the covering insulating layer and the functional device. Thus, a stress generated on an interface between the covering insulating layer and the functional device can be relaxed, thereby can suppress an occurrence of warpage. Also, the stress relaxation in the functional device-embedded substrate according to the present invention can prevent a damage of the functional device such as a semiconductor chip.

Also, the functional device-embedded substrate according to the present invention can reduce warpage and thus resulting in an increase of manufacturing yield.

Hereinafter, exemplary embodiments of the present invention will be described in detail with reference to the drawings. Although the following exemplary embodiments will be described in terms of a case where a semiconductor chip is used as a functional device, the present invention is not specifically limited to this case.

### (Exemplary Embodiment 1)

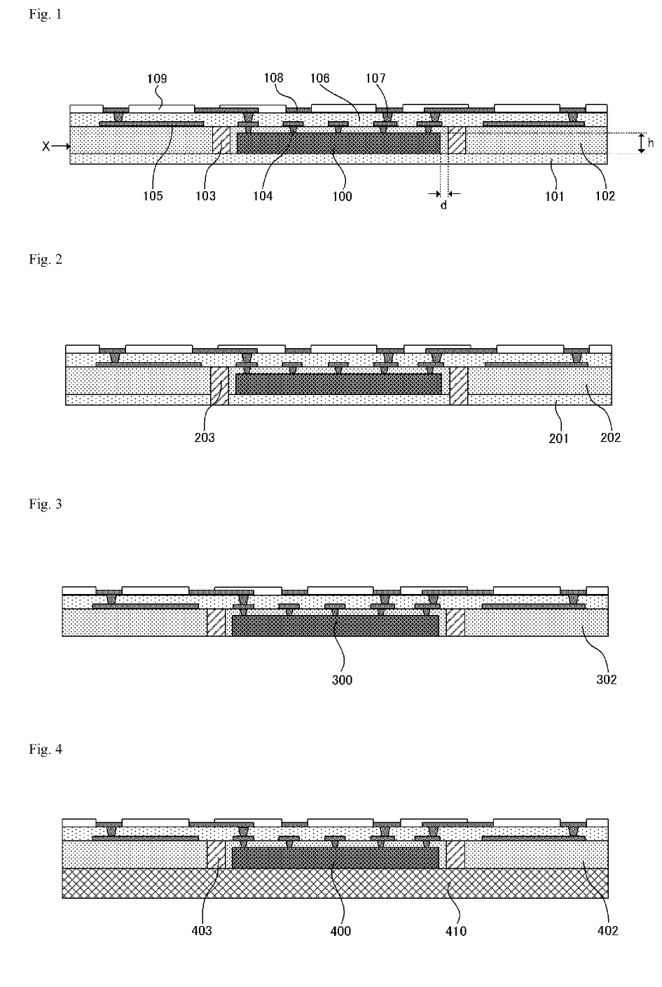

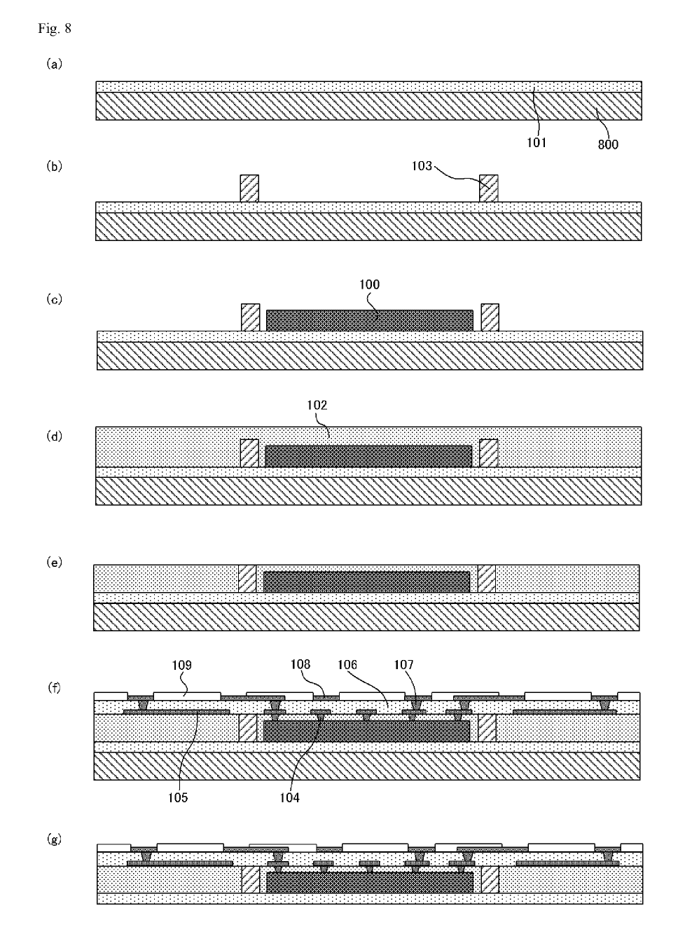

FIG. 1 is a cross-sectional diagram for illustrating a functional device-embedded substrate according to the present exemplary embodiment. Also, FIG. 8 is a schematic cross-sectional diagram of a horizontal cross-section along arrow A in FIG. 1.

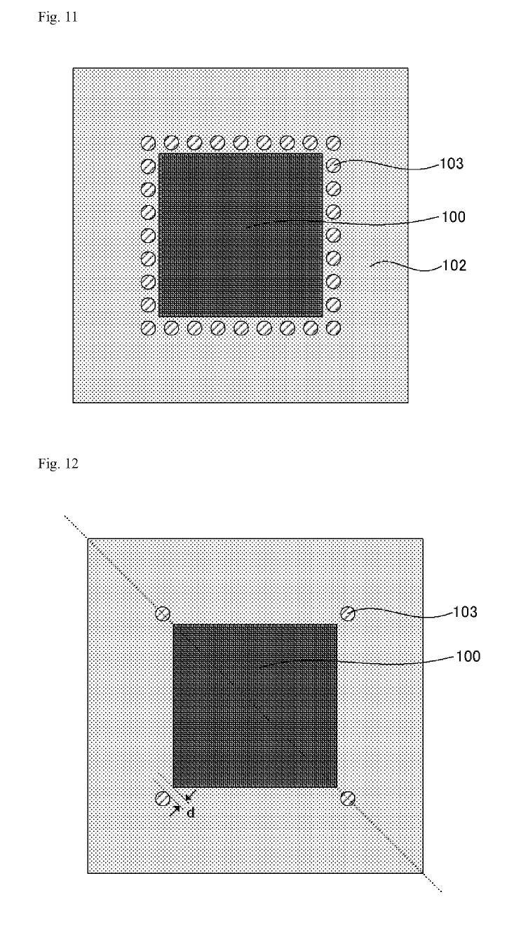

In FIG. 1, a functional device 100 is arranged on a back-side insulating layer 101 with a surface including electrode terminals facing up, and the electrode terminal surface and side surfaces of the functional device 100 are covered by a covering insulating layer 102. An adhesive (not illustrated) may be arranged between the back-side insulating layer 101 and the functional device 100. Then, first pillar structures 103 are formed in the vicinity of the side surfaces of the functional device inside the covering insulating layer 102. As illustrated in FIGS. 1 and 11, the first pillar structures 103 are arranged in the vicinity of the side surfaces of the functional device 100 in the covering insulating layer 102, and are each arranged at a position where a shortest distance d1 from the side surface of the functional device 100 to a side surface of the first pillar structure is smaller than a thickness h of the functional device 100. FIG. 11 is a horizontal cross-sectional diagram along arrow X in FIG. 1. Hereinafter, a shortest distance from the functional device to the respective first pillar structures is also abbreviated as d1.

A wiring layer 105 is provided on the covering insulating layer 102. Also, device vias 104 electrically connecting the wiring layer 105 and the functional device 100 are provided in the covering insulating layer 102. The wiring layer 105 includes wirings such as a signal wiring, a power supply wiring or a ground wiring. In the present description, a wiring layer arranged on the electrode terminal surface of the functional device (for example, the wiring layer 105 in FIG. 1) is also referred to as a front-side wiring layer.

The wiring layer 105 is covered by a wiring insulating layer 106, and on the wiring insulating layer 106, a solder resist 109 is provided. Inside the solder resist 109, external connection terminals 108 used for connection with, e.g., an external substrate is provided. Also, wiring vias 107 electrically connecting the wiring layer 105 and the external connection terminals 108 are provided in the wiring insulating layer 106.

On the external connection terminals 108, for example, BGA balls are arranged to connect the external connection terminals 108 with an external substrate such as a motherboard. Alternatively, the external connection terminals 108 may be configured so that the signal wiring and the ground wiring are exposed in openings of the solder resist 109. In other words, a second wiring layer including a ground wiring and a signal wiring are provided on the wiring insulating layer 106, and the solder resist 109 can be formed on the ground wiring and the signal wiring so that the ground wiring and the signal wiring are exposed. Also, surfaces of the external connection terminals can be protected so as to prevent, for example, a flowage of a solder.

Here, in the present invention, the first pillar structure 103 is comprised of a material having a thermal expansion coefficient between thermal expansion coefficients of the functional device 100 and the covering insulating layer 102. Also, as described above, the first pillar structure 103 is arranged at a position where a shortest distance d1 from the side surface of the functional device 100 to a side surface of the first pillar structure is smaller than the thickness h of the functional device 100. With such configuration, a part of the covering insulating layer that is in an area including the first pillar structure can be regarded as having a reduced thermal expansion coefficient, thereby substantively reducing the difference between the thermal expansion coefficients of the covering insulating layer and the functional device. Thus, a stress generated on an interface between the covering insulating layer and the functional device can be relaxed, thus resulting in suppression of occurrence of warpage. Also, the stress relaxation can prevent damage of the functional device such as a semiconductor chip.

Also, the present invention may include a second pillar structure in the covering insulating layer in addition to the first pillar structure, the second pillar structure being arranged at a position where its shortest distance from the functional device is larger than the thickness of the functional device.

Also, since it is effective that the first pillar structure is arranged at position where a stress concentrates on the embedded functional device 100, it is preferable that the first pillar structure be arranged around a corner of the functional device. In this case, a shortest distance d1 from a corner of the functional device to a side surface of the first pillar structure is smaller than the thickness h of the functional device. For example, as illustrated in the horizontal cross-sectional diagram in FIG. 12, the first pillar structures are respectively arranged at each of the four corners of the functional device such as a semiconductor chip. Arrangement of the first pillar structure around the corner enables more effective relaxation of a stress that tends to concentrate on the corner portion of the functional device such as a semiconductor chip. Also, as illustrated in FIG. 12, it is preferable that the first pillar structures be arranged on extensions of diagonals of the functional device 100 in a horizontal cross section, and it is preferable that the first pillar structures 103 be arranged with a center of each of the first pillar structures 103 on the extension of the corresponding diagonal of the functional device. Also, it is preferable that the distances d1 from the respective corners of the semiconductor chip to the side surfaces of the respective first pillar structures be equal to one another.

Also, it is preferable that the first pillar structure be formed in an area within a range in which a distance from the corresponding side surface of the functional device is no more than 10×d1, preferably, no more than 7×d1, more preferably no more than 5×d1.

Also, although in FIGS. 1 and 11, the pillar structure has a circular pillar shape, the shape of the pillar structure is not limited to this shape. The pillar structure can have, for example, a circular pillar shape or a polygonal pillar shape. Furthermore, the pillar structure may be hollow. Where the first pillar structure has a circular pillar shape, a diameter of a horizontal cross-section thereof is, for example, 50 to 500 μm, preferably, 100 to 300 μm.

Also, as illustrated in FIG. 11, for further stress relaxation, it is preferable that a plurality of first pillar structures 103 be aligned so that the first pillar structures 103 also face the side surfaces of the functional device. For example, as illustrated in FIG. 11, first pillar structures can be provided not only around the corners of the functional device but also at positions facing the side surfaces. In such case, a shortest distance d1 from the respective side surfaces of the functional device to the respective first pillar structures is smaller than the thickness h of the functional device. Also, where the first pillar structures are polygonal columns, it is preferable that the first pillar structures be arranged so that a side surface of each of the first pillar structures and a corresponding surface of the functional device are parallel to each other.

As described above, the pillar structure is comprised of a material having a thermal expansion coefficient between the thermal expansion coefficients of the functional device and the insulating layer. For the material of the pillar structure, for example, a conductor material or an insulator material can be used.

Examples of the conductor material include metals such as Au, Cu, Al, Ag, Fe, Ti, Ni, Pt and Pd and alloys thereof. From among these, Au or Cu is preferably used. Also, a conductor having a large rigidity such as SUS is preferable. Where a material for the pillar structure is a conductor, the pillar structures can also be used as vias. Furthermore, a material that is the same as that used for vias can also be used for the pillar structure. In such case, the pillar structure can be formed by plating according to the same method for forming the vias. In such case, what is called a filled via, i.e., a structure in which a via opening is filled with a metal conductor is preferable. Examples of the other formation methods include a method in which the pillar structure is arranged in the vicinity of the side surface of the functional device in advance by, e.g., cutting wire-like, thin metal stick and then the pillar structure is buried in a resin.

Examples of the insulator material include resins and ceramic. Since it is preferable that the pillar structure have rigidity, it is preferable to use an insulator having a large rigidity such as ceramic. It is preferable to use an insulator as a material for the pillar structure because the pillar structure can be formed in the covering insulating layer without hindering a wiring design of a wiring layer formed on the covering insulating layer.

Also, for the functional device, a semiconductor material such as silicon is mainly used, and for example, a semiconductor chip such as an LSI is fabricated using silicon. Thus, the thermal expansion coefficient of the functional device is substantially equal to a thermal expansion coefficient of silicon, and have a value of approximately 2 to 3×10̂−6 [1/° C.]. Meanwhile, for the covering insulating layer covering the functional device, an organic resin having an excellent fluidity (for example, epoxy-based resin), and a thermal expansion coefficient of such organic resin is, for example, approximately 50×10̂−6[1/° C.]. Accordingly, the thermal expansion coefficient of the pillar structures can be made to be, for example, 5×10̂−6 to 30×10̂−6 [1/° C.], preferably, 7×10̂−6 to 20×10̂−6 [1/°C.], more preferably 8×10̂−6 to 15×10̂−6[1/° C.]. Thermal expansion coefficients of metals are approximately 10 to 20×10̂−6[1/° C.], and thus, a metal can preferably be used for the pillar structures. For example, Cu has a thermal expansion coefficient of approximately 17×10̂−6[1/° C.], Fe has a thermal expansion coefficient of approximately 12×10̂−6[1/° C.], and Pt has a thermal expansion coefficient of 9×10̂−6 [1/° C.].

For a material of the covering insulating layer, a resin having an insulating property can be used, and an insulator used for a normal wiring substrate can be used. Examples of the material for the covering insulating layer include, e.g., epoxy resin, epoxy acrylate resin, urethane acrylate resin, polyester resin, phenol resin, polyimide resin and polynorbornene resin. Furthermore, the examples also include, e.g., BCB (Benzocyclobutene) and PBO (Polybenzoxazole). From among these, polyimide resin and PBO are excellent in mechanical characteristics such as film strength, tensile elasticity and breaking extension coefficient, enabling provision of high reliability. The material for the covering insulating layer may be either photosensitive or non-photosensitive. The covering insulating layer may include a plurality of layers; however, in such case, it is preferable to use a same material for the plurality of layers.

Also, the thermal expansion coefficient of the material for the covering insulating layer is, for example, 35×10̂−6 to 70×10̂−6 [1/° C.], preferably 40×10̂−6 to 60×10̂−6 [1/° C.]. For the covering insulating layer, it is preferable to use an organic resin having an excellent fluidity for covering the functional device, and a thermal expansion coefficient of such organic resin is, for example, approximately 50×10̂−6 [1/° C.].

Examples of the functional device include active components such as a semiconductor chip and passive components such as a condenser. Examples of the semiconductor chip include, e.g., transistors, ICs and LSIs. Although the semiconductor chip is not specifically limited, for example, a CMOS (Complementary Metal Oxide Semiconductor) can be selected. In the case of a semiconductor chip, the thickness of the functional device is, for example, 50 to 200 μm. In the case of a chip-type passive component, the thickness is, for example, 200 to 400 μm. Also, in the case of a thin-film-like passive, the thickness is, for example, 100 to 200 μm. In the present invention, for the functional device, a semiconductor chip can preferably be used, and also, a semiconductor chip having a thickness of 50 to 200 μm can preferably be used.

For example, where the semiconductor chip has a thickness of 50 μm, the distance d1 between the side surface of the semiconductor chip and the side surface of the first pillar structure is preferably no more than 40 μm and more preferably no more than 10 μm. In such case, the first pillar structure can have a diameter of, for example, 100 μm.

Also, for a semiconductor chip as the functional device, a semiconductor chip having a terminal surface of, for example, full-grid type or peripheral pad type can be used. Furthermore, a method for connection with a wiring layer is not specifically limited, e.g., flip-chip connection, copper post connection or laser via connection may be used.

Also, it is preferable that the thickness of the pillar structure be equal to or larger than the thickness of the functional device to more effectively reduce a stress resulting from the difference between the thermal expansion coefficients of the covering insulating layer and the functional device. For example, when a semiconductor chip is selected as the functional device, it is preferable that the thickness of the pillar structure be equal to or larger than a thickness of the semiconductor chip. Also, the thickness of the pillar structure is preferably equal to or smaller than the thickness of the covering insulating layer and is more preferably equal to the thickness of the covering insulating layer. Also, it is preferable that the pillar structure be provided so as to penetrate through the covering insulating layer and have a thickness equal to the thickness of the covering insulating layer. The thickness in such range can effectively suppress warpage.

Also, the pillar structures may be in contact with one another.

For conductors used for the wiring layers and the vias, which are not specifically limited, for example, a metal including at least one selected from a group consisting of copper, silver, gold, nickel, aluminum and palladium or an alloy including some of the above as main components. From among them, Cu is preferably used as the conductors from the perspective of electric resistance value and cost.

Next, a method for fabricating the functional device-embedded substrate illustrated in FIG. 1 will be described with reference to FIG. 8. FIG. 8 is a cross sectional process diagram schematically illustrating a process of manufacturing the functional device-embedded substrate according to the exemplary embodiment in FIG. 1. In the below description, a semiconductor chip is used as the functional device. Also, the present invention is not limited to the below manufacturing method.

First, as illustrated in FIG. 8(a), a metal plate 800 is provided as a support, and a back-side insulating layer 101 is formed on the metal plate 800.

Next, as illustrated in FIG. 8(b), first pillar structures 103 are formed on the back-side insulating layer 101. Here, the first pillar structures 103 are formed taking a distance between the first pillar structures 103 and a semiconductor chip, which is arranged in a subsequent step, into account.

The first pillar structures 103 can be formed by, for example a plating method.

Next, as illustrated in FIG. 8(c), a semiconductor chip 100 is arranged between the first pillar structures 103 on the back-side insulating layer 101. Here, the semiconductor chip 100 is placed so that a shortest distance between side surfaces of the semiconductor chip 100 and side surfaces of the first pillar structures 103 is smaller than a thickness of the semiconductor chip 100.

Furthermore, the semiconductor chip 100 is arranged with electrode terminals (not illustrated) facing up. Furthermore, the semiconductor chip 100 may be mounted with an adhesive (not illustrated) between the semiconductor chip 100 and the back-side insulating layer 101. For the adhesive, for example, an epoxy resin, an epoxy acrylate resin, an urethane acrylate resin, a polyester resin, a phenol resin or a polyimide resin may be used.

Next, as illustrated in FIG. 8(d), a covering insulating layer 102 is arranged on the semiconductor chip 100 and the back-side insulating layer 101.

Subsequently, as illustrated in FIG. 8(e), the covering insulating layer 102 is ground for planarization until the first pillar structures 103 are exposed.

Next, as illustrated in FIG. 8(f), device vias 104, a wiring layer 105, a wiring insulating layer 106, wiring vias 107, external connection terminals 108 and a solder resist 109 are formed.

A method for forming the wiring insulating layer includes, e.g., a transfer molding method, a compression molding method, a printing method, vacuum pressing, vacuum laminating, a spin coating method, a die coating or a curtain coating method.

When the material used for the insulating layer has photosensitive, prepared holes can be formed by a photolithography method. When the material used for the insulating layer is non-photosensitive or has a low pattern resolution, prepared holes can be formed by a laser processing method, a dry etching method or an abrasive blasting method.

Also, for a method for forming device vias or wiring vias, e.g., electrolytic plating, non-electrolytic plating, a printing method or a molten metal suction method can be used.

Also, for device vias connecting with the electrode terminals of the semiconductor chip, a method in which metal posts for current application are provided in advance on the electrode terminals, the covering insulating layer 102 is formed and then surfaces of the insulating materials are shaved by means of, e.g., grinding to make surfaces of the metal posts be exposed to form vias may be employed. Examples of the shaving method include buffing and CMP.

The wiring layer can be formed by means of, for example, a subtractive process, a semi-additive process or a full additive process, using, for example, a metal such as Cu, Ni, Sn or Au.

The subtractive process is disclosed in, for example, in JP10-51105A. The subtractive process is a method in which etching is performed using a resist obtained by forming a copper foil provided on a substrate or a resin into a desired pattern as an etching mask and subsequently the resist is removed to obtain a desired wiring pattern. The semi-additive process is disclosed in, for example, JP9-64493A. The semi-additive process is a method in which after formation of a power feed layer, a resist is formed into a desired pattern, electrolyte plating is deposited in opening portions of the resist, and after removal of the resist, the power feed layer is etched to obtain a desired wiring pattern. The power feed layer can be formed by means of, for example, non-electrolyte plating, a sputtering method and a CVD method. The full additive process is disclosed in, for example, JP6-334334A. In the full additive process, first, a non-electrolyte plating catalyst is absorbed on a surface of a substrate or a resin and then a pattern is formed using a resist. Then, with the resist left as an insulating layer, the catalyst is activated to make a metal be deposited in opening portions of the insulating layer by means of a non-electrolyte plating method to obtain a desired wiring pattern.

The external connection terminals 108 may double as a signal wiring or a ground wiring, and in this case, a solder resist is etched so that the signal wiring or the ground wiring is partially exposed, whereby external connection terminals can be formed.

Next, as illustrated in FIG. 8(g), the metal plate 800 is removed by means of, e.g., etching, thereby the functional device-embedded substrate described in FIG. 1 can be obtained.

### Exemplary Embodiment 2

FIG. 1 illustrates a functional device-embedded substrate including first pillar structures penetrating through a covering insulating layer 102 only. Also, as illustrated in FIG. 2, first pillar structures 203 according to the present exemplary embodiment can be configured so as to penetrating though both a back-side insulating layer 201 and a covering insulating layer 202.

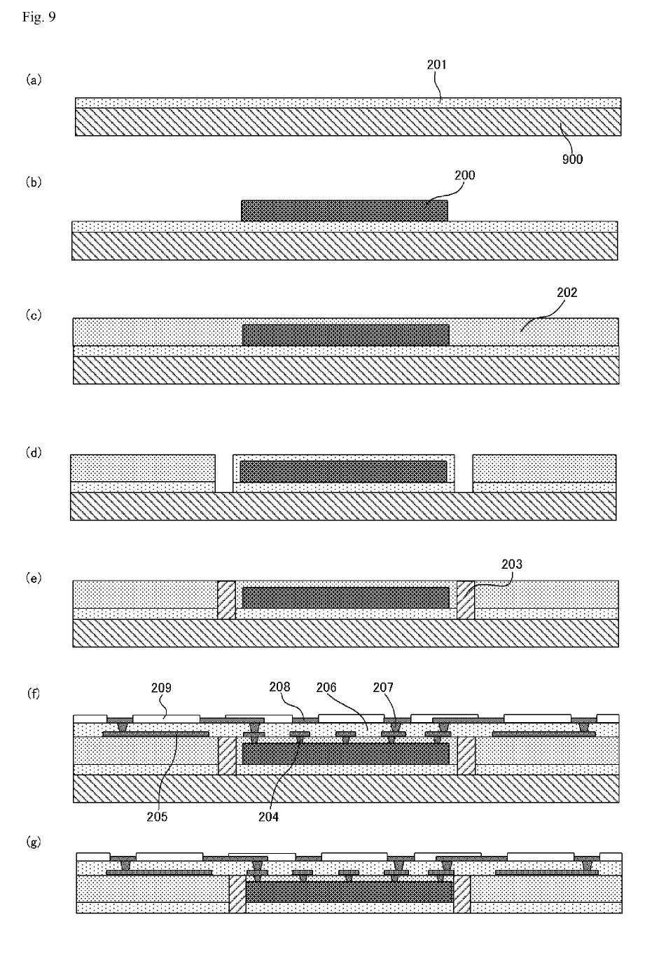

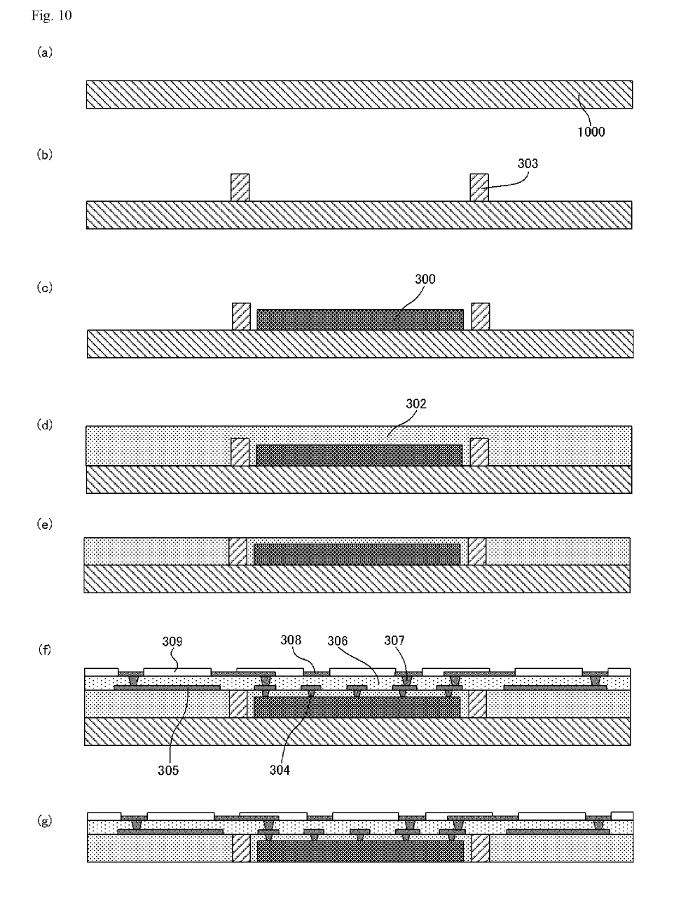

A method for fabricating the functional device-embedded substrate illustrated in FIG. 2 will be described with reference to FIG. 9. FIG. 9 is a cross-sectional process diagram schematically illustrating a process of manufacturing a functional device-embedded substrate according to the exemplary embodiment in FIG. 2. In the below description, a semiconductor chip is used as a functional device.

First, as illustrated in FIG. 9(a), a metal plate 900 is provided as a support, and a back-side insulating layer 201 is formed on the metal plate 900.

Next, as illustrated in FIG. 9(b), a semiconductor chip 200 is placed on the back-side insulating layer 201.

Next, as illustrated in FIG. 9(c), a covering insulating layer 202 is arranged on the semiconductor chip 200 and the back-side insulating layer 201.

Next, as illustrated in FIG. 9(d), openings for forming first pillar structures are formed in the back-side insulating layer 201 and the covering insulating layer 202. At this time, the openings are formed so that a shortest distance between the side surfaces of the semiconductor chip 200 and the side surfaces of the resulting first pillar structures 203 is smaller than a thickness of the semiconductor chip 200.

Next, as illustrated in FIG. 9(e), the first pillar structures 203 are formed in the openings.

At this time, use of a via material as a material for the first pillar structures 203 enables easy formation of the first pillar structures 203 by means of, e.g., a plating method.

Next, as illustrated in FIG. 9(f), device vias 204, a wiring layer 205, a wiring insulating layer 206, wiring vias 207, external connection terminals 208 and a solder resist 209 are formed.

Next, as illustrated in FIG. 9(g), the metal plate 900 is removed by means of, e.g., etching, thereby the functional device-embedded substrate illustrated in FIG. 2 can be obtained.

In the exemplary embodiment illustrated in FIG. 2, if a wiring layer is further provided on the lower side, at least one of the first pillar structures 203 can be used as a via.

### Exemplary Embodiment 3

Although FIG. 1 illustrates a mode in which a back-side insulating layer 101 is provided, the present invention is not limited to this mode, and as illustrated in FIG. 3, a configuration in which a back-side insulating layer is not provided and the back surfaces of a functional device 300 and a covering insulating layer 302 are exposed can be employed.

A method for fabricating the functional device-embedded substrate illustrated in FIG. 3 will be described with reference to FIG. 10. FIG. 10 is a cross-sectional process diagram schematically illustrating a functional device-embedded substrate according to the exemplary embodiment in FIG. 3. In the below description, a semiconductor chip is used as a functional device.

First, as illustrated in FIG. 10(a), a metal plate 1000 is provided as a support.

Next, as illustrated in FIG. 10(b), first pillar structures 303 are formed on the metal plate 1000. At this time, the first pillar structures 303 are formed taking a distance between the first pillar structures 303 and a semiconductor chip, which is arranged in a subsequent step, into account.

The first pillar structures 303 can be formed using, for example, a semi-additive process or a subtractive process.

Next, as illustrated in FIG. 10(c), a semiconductor chip 300 is arranged between the first pillar structures 303 on the metal plate 1000. At this time, the semiconductor chip 300 is arranged so that a shortest distance between side surfaces of the semiconductor chip 300 and side surfaces of the respective first pillar structures 303 is smaller than a thickness of the semiconductor chip 300. Also, the semiconductor chip 300 is arranged with electrode terminals (not illustrated) facing up.

Next, as illustrated in FIG. 10(d), a covering insulating layer 302 is arranged on the semiconductor chip 300 and the metal plate 1000.

Subsequently, as illustrated in FIG. 10(e), the covering insulating layer 302 is ground for planarization until the first pillar structures 303 are exposed.

Next, as illustrated in FIG. 10(f), device vias 304, a wiring layer 305, a wiring insulating layer 306, wiring vias 307, external connection terminals 308 and a solder resist 309 are formed.

Next, as illustrated in FIG. 10(g), the metal plate 1000 is removed by means of, e.g., etching, thereby the functional device-embedded substrate illustrated in FIG. 3 can be obtained.

### Exemplary Embodiment 4

Also, as illustrated in FIG. 4, a functional device substrate according to the present invention may include a support 410 in order to suppress warpage. For a material for the support 410, it is preferable to use a metal plate from the perspective of easiness in manufacturing process; however, the material for the support 410 is not limited to this.

For a material for the metal plate, which is not specifically limited, for example, a metal including at least one selected from a group consisting of copper, silver, gold, nickel, aluminum and palladium or an alloy including some of the above as main components. From among them, it is preferable to use copper as the material for the metal plate from the perspective of electrical resistance value and cost. The metal plate also functions as an electromagnetic shield, and thus, is expected to reduce unwanted electromagnetic radiation.

In FIG. 4, a functional device 400 and a covering insulating layer 402 covering the functional device 400 are provided on the support 410. Also, in the covering insulating layer 402, first pillar structures 403 are provided so as to penetrate through the layer. An adhesive may be provided between the functional device 400 and the support 410.

### Exemplary Embodiment 5

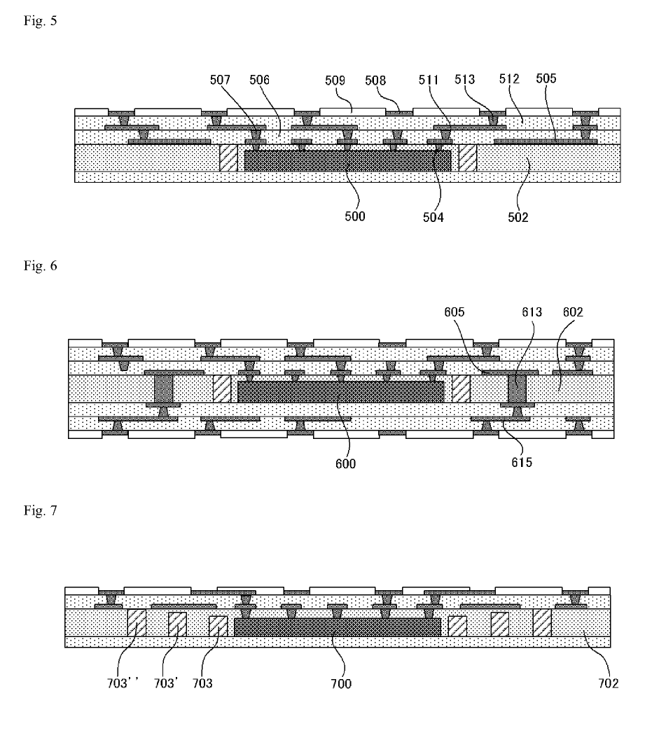

Although FIG. 1 illustrates a mode in which one wiring layer (front-side wiring layer) is formed on the electrode terminal surface of a functional device 100, the present invention is not limited to this mode, and as illustrated in FIG. 5, two or more front-side wiring layers can be formed on the electrode terminal surface of a functional device 500.

In FIG. 5, a first front-side wiring layer 505 is formed on a covering insulating layer 502. The first front-side wiring layer 505 is electrically connected to electrode terminals of the functional device 500 through device vias 504 formed inside the covering insulating layer 502. The first wiring insulating layer 506 is formed so as to cover the first front-side wiring layer 505, and a second front-side wiring layer 511 is formed on the first wiring insulating layer 506. The second front-side wiring layer 511 is electrically connected to the first front-side wiring layer 505 through first wiring vias 507 formed inside the first wiring insulating layer 506. A second wiring insulating layer 512 is formed so as to cover the second front-side wiring layer 511, and external connection terminals 508 and a solder resist 509 are formed on the second wiring insulating layer 512. The external connection terminals 508 are electrically connected to the second front-side wiring layer 511 through second wiring vias 513 formed inside the second wiring insulating layer 512.

### Exemplary Embodiment 6

Also, in the present invention, one or more wiring layers can be provided not only on the electrode terminal surface of a functional device, but also, for example, as illustrated in FIG. 6, on a surface opposite to the electrode terminal surface. In the present specification, a wiring layer provided on the surface opposite to the electrode terminals of the functional device is referred also to a back-side wiring layer. Provision of a wiring layer on each of a front side and a back side of a functional device 600 enables enhancement in the degree of design freedom for wiring. Furthermore, the symmetry of the structure is enhanced, thus resulting in further reduction in warpage of the substrate. FIG. 6 illustrates a mode in which one back-side wiring layer 615 is provided on the surface opposite to an electrode terminal surface, that is, a back side of a functional device in the configuration illustrated in FIG. 3. The back-side wiring layer 615 is electrically connected to electrode terminals of the functional device through interlayer vias 613 provided in a covering insulating layer 602 and the first front-side wiring layer 605.

Also, when providing a wiring layer on the back side of the functional device, it is necessary to provide interlayer vias for electrically connecting the upper and lower wiring layers in the covering insulating layer 602. In the present exemplary embodiment, when a metal is used for a material for each of the first pillar structures and the second pillar structures, as described above, at least one of the pillar structures can be used as an interlayer via.

### Exemplary Embodiment 7

Also, it is not necessary that pillar structures be provided so as to penetrate through a covering insulating layer, and pillar structures may be arranged so as to be buried in the covering insulating layer. In this case, in order to more effectively reduce a stress resulting from a difference in thermal expansion coefficient between the insulating layer and a functional device, it is preferable that a thickness in a vertical direction of the pillar structures be equal to or larger than a thickness of the functional device (semiconductor chip) and equal to or smaller than a thickness of the covering insulating layer.

Also, as illustrated in FIG. 7, first pillar structures 703 and second pillar structures 703′ and 703″ are formed as pillar structures. It is preferable that the lower surfaces of the pillar structures be on a same plane as a lower surface of the covering insulating layer, and the upper surfaces of the pillar structures are located at a position higher than an upper surface of the functional device. Furthermore, as illustrated in FIG. 7, it is preferable that the height of the pillar structures increase with increasing distance of the pillar structures from the functional device. Such configuration is preferable because a thermal expansion coefficient of the covering insulating layer can be regarded as gradually decreasing from the functional device toward the outside of the substrate. In other words, an area in which a large thermal expansion coefficient difference occurs can be reduced, thereby enabling further reduction of occurrence of warpage.

### Exemplary Embodiment 8

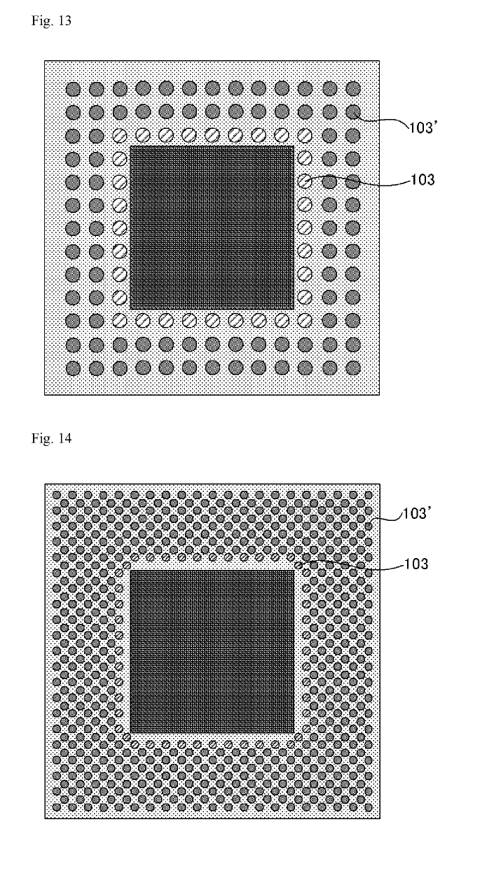

As illustrated in FIG. 13, besides the first pillar structures arranged at positions where the distance d1 is smaller than the thickness h of the functional device, for more stress relaxation and warpage reduction, second pillar structures arranged at positions where the distance d1 is equal to or larger than the thickness h of the functional device can be formed in a covering insulating layer.

For example, as illustrated in FIG. 13, several rows of second pillar structures can be arranged outside the first pillar structures. Also, as illustrated in FIG. 13, the first pillar structures and the second pillar structures can be arranged in a grid. Furthermore, as illustrated in FIG. 14, the first pillar structures and the second pillar structures can be arranged in a staggered arrangement. The grid or staggered arrangement of pillar structures enables formation of many pillar structures in an insulating layer, and thus, enabling more effective reduction of warpage.

### Exemplary Embodiment 9

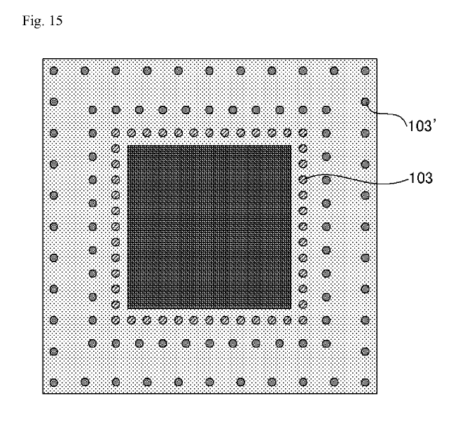

Also, as illustrated in FIG. 15, intervals of the pillar structures arranged in a grid can be made to increase with increasing distance of the pillar structures from a semiconductor chip in the functional device substrate including pillar structures arranged in a grid, which has been described in exemplary embodiment 3. Such configuration is preferable because a thermal expansion coefficient of a covering insulating layer can be regarded as gradually decreasing from the functional device toward the outside. In other words, an area in which a large thermal expansion coefficient difference occurs can be reduced, thereby enabling further reduction of warpage.

Also, the pillar structures can be arranged so as to be on lines similar to lines of a horizontal cross-sectional shape of a functional device. The similar lines here are imaginary ones and not included in the configuration of the functional device-embedded substrate.

The present application claims priority from Japanese Patent Application No. 2010-059316 filed in Japan on Mar. 16, 2010, the entire disclosure of which is incorporated herein.

Although the invention according to the present application has been described with reference to the exemplary embodiments and examples, the invention according to the present application is not limited to the above exemplary embodiments and examples. Various alterations that can be understood by a person skilled in the art can be made to the configuration and details of the invention according to the present application as long as such alterations fall within the scope of the invention according to the present application.

### REFERENCE SIGNS LIST

100, 200, 300, 400, 500, 600, 700 functional device (or semiconductor chip)
101, 201 back-side insulating layer
102, 202, 302, 402, 502, 602, 702 covering insulating layer
103, 203, 303, 403, 703 first pillar structure
103′, 703′, 703″ second pillar structure
104, 204, 304, 504 device via
105, 205, 305, 505, 511, 605 front-side wiring layer
106, 206, 306, 505, 512 wiring insulating layer
107, 207, 307, 507, 513 wiring via
108, 208, 308, 508 external connection terminal
109, 209, 309, 509 solder resist
613 interlayer via
615 back-side wiring layer

What is claimed is:

1. A functional device-embedded substrate comprising at least a functional device including an electrode terminal, and a covering insulating layer covering at least an electrode terminal surface and a side surface of the functional device, wherein
the functional device-embedded substrate comprises a first pillar structure around the functional device inside the covering insulating layer, the first pillar structure being comprised of a material having a thermal expansion coefficient between thermal expansion coefficients of the functional device and the covering insulating layer, and
the first pillar structure is arranged at a position where a shortest distance from a side surface of the functional device to a side surface of the first pillar structure is smaller than a thickness of the functional device.

2. The functional device-embedded substrate according to claim 1, wherein the first pillar structure is arranged around a corner of the functional device.

3. The functional device-embedded substrate according to claim 1, wherein the first pillar structure is arranged also at a position facing a side surface of the functional device.

4. The functional device-embedded substrate according to claim 1, further comprising a second pillar structure inside the covering insulating layer, the second pillar structure comprised of a material having a thermal expansion coefficient between the thermal expansion coefficients of the functional device and the covering insulating layer,
wherein the second pillar structure is arranged at a position where a shortest distance from a side surface of the functional device to a side surface of the second pillar structure is equal to or larger than the thickness of the functional device.

5. The functional device-embedded substrate according to claim 4, wherein a plurality of the first columnar structures and a plurality of the second columnar structures are arranged in a grid or a staggered arrangement.

6. The functional device-embedded substrate according to claim 5, wherein a pitch of the grid increases as the distance from the functional device increases.

7. The functional device-embedded substrate according to claim 5, wherein the first pillar structures and the second pillar structures each have a thickness that increases as the distance of the first pillar structures and the second pillar structures from the functional device increases.

8. The functional device-embedded substrate according to claim 1, wherein the first pillar structure or the second pillar structure has a thickness equal to or larger than the thickness of the functional device.

9. The functional device-embedded substrate according to claim 1, wherein the first pillar structure is formed so as to penetrate through the covering insulating layer and have a thickness equal to a thickness of the covering insulating layer.

10. The functional device-embedded substrate according to claim 1, wherein the first pillar structure is comprised of an insulator material.

11. The functional device-embedded substrate according to claim 1, wherein the first pillar structure includes a conductor material.

12. The functional device-embedded substrate according to claim 1, wherein the first pillar structure has a circular column shape or a polygonal column shape.

13. The functional device-embedded substrate according to claim 1, further comprising a front-side wiring layer on the electrode terminal surface of the functional device, the front-side wiring layer being electrically connected to the electrode terminal.

14. The functional device-embedded substrate according to claim 1, further comprising a back-side wiring layer on a surface opposite to the electrode terminal surface of the functional device, the back-side wiring layer being electrically connected to the electrode terminal through at least an interlayer via provided in the covering insulating layer.

15. The functional device-embedded substrate according to claim 1, further comprising a support on a surface opposite to the electrode terminal surface of the functional device.

16. The functional device-embedded substrate according to claim 11 further comprising: a front-side wiring layer on the electrode terminal surface of the functional device, the front-side wiring layer being electrically connected to the electrode terminal; and
a back-side wiring layer on a surface opposite to the electrode terminal surface of the functional device, the back-side wiring layer being electrically connected to the electrode terminal,
wherein the first pillar structure doubles as an interlayer via electrically connecting the front-side wiring layer and the back-side wiring layer.

17. The functional device-embedded substrate according to claim 1, wherein the first pillar structure is formed in an area having a distance from the side surface of the functional device in a range of no more than 10×d1, d1 represents the shortest distance.

18. The functional device-embedded substrate according to claim 1, wherein the first pillar structure has a thermal expansion coefficient of 5×10̂−6 to 30×10̂−6 [1/° C.], and the covering insulating layer has a thermal expansion coefficient of 35×10̂−6 to 70×10̂−6 [1/° C.].

19. The functional device-embedded substrate according to claim 1, wherein the functional device is a semiconductor chip.

20. The functional device-embedded substrate according to claim 19, wherein the semiconductor chip has a thickness of 50 to 200 μm.
